(19) United States
(12) Patent Application Publication
(10) Pub. No.: US 2020/0091225 A1
(43) Pub. Date: Mar. 19, 2020

(54) MICRO LED DISPLAY PANEL AND MANUFACTURING METHOD THEREOF

(71) Applicant: SHENZHEN CHINA STAR OPTOELECTRONICS TECHNOLOGYCO.,LTD, Shenzhen, Guangdong (CN)

(72) Inventors: Qingdou YANG, Shenzhen, Guangdong (CN); Zhiwu WANG, Shenzhen, Guangdong (CN)

(21) Appl. No.: 15/751,124

(22) PCT Filed: Jan. 17, 2018
(86) PCT No.: PCT/CN2018/073037

§ 371 Date: Feb. 7, 2018

(30) Foreign Application Priority Data
Dec. 26, 2017 (CN) 201711432351.X

(51) Int. Cl. H01L 27/15; H01L 27/32

(52) U.S. Cl. CPC H01L 27/156; H01L 27/3248

(57) ABSTRACT

A Micro LED display panel and manufacturing method thereof are provided. The Micro LED display panel includes TFT substrate, bottom electrode positioned on top of the TFT substrate, Micro LED chip positioned on the bottom electrode, top electrode positioned on top of the Micro LED chip, and first passivation layer covering the TFT substrate and the Micro LED chip. A plurality of the bottom electrode is provided, and positioned at interval on top of the TFT substrate; the bottom of the bottom electrode is extending and conducting with a source or a drain of the TFT substrate. This disclosure directly manufacturing Micro LED chip connecting the bottom electrode and the top electrode for greatly decreases thickness of the display panel, and also achieves narrow frame. Furthermore, beside the Micro LED chip is entire passivation layer such that it does not need to multiple manufacturing method, simplify the manufacturing steps.

### RELATED APPLICATIONS

The present application is a National Phase of International Application Number PCT/CN2018/073037, filed Jan. 17, 2018, and claims the priority of China Application No. 201711432351.X, filed Dec. 26, 2017.

### FIELD OF THE DISCLOSURE

The disclosure relates to a semiconductor manufacturing technical field, and more particularly to a micro LED display panel and a method of manufacturing micro LED display panel.

### BACKGROUND

With the increasing consumers' requirements, the lightening and thinning of each module in the display device is more and more concerned and focused by people. Usually, the display device includes display panel and backlight module, the backlight module could emit the light as the backlight source of the display panel. The currently backlight module is separated by position of the light source and light guide plate, direction-type and lateral-type. Wherein, the direction type is limited by the structure setting so that it does not have advantage in thickness. And then the lateral backlight source of lateral-type has a certain width frame such that hard to narrow, and limits entire frame design. Therefore, no matter the lateral-type backlight or direction-type backlight, they both hard to improve the thickness and narrow frame of the display device at the same time.

### SUMMARY

A technical problem to be solved by the disclosure is to provide a Micro LED display panel and a method of manufacturing Micro LED display panel with super thin thickness and super narrow frame.

An objective of the disclosure is achieved by following embodiments. In particular a Micro LED display panel, comprising a TFT substrate, a bottom electrode positioned on top of the TFT substrate, a Micro LED chip positioned on the bottom electrode, a top electrode positioned on top of the Micro LED chip, and a first passivation layer covering the TFT substrate and the Micro LED chip, wherein a plurality of the bottom electrode is provided, and positioned at interval on top of the TFT substrate, the bottom of the bottom electrode is extending and conducting with a source or a drain of the TFT substrate, at least part of the top electrode is positioned outside the first passivation layer.

In an embodiment, the Micro LED display panel further comprising a bonded layer, the Micro LED chip is bonded to the bottom electrode by the bonded layer.

In an embodiment, the Micro LED chip comprising an emitting-light layer, a N type semiconductor layer and a P type semiconductor layer are respectively positioned beside the emitting-light layer, a transparent conducting layer positioned on surface of the P type semiconductor layer and a P type metal electrode positioned on surface of the transparent conducting layer, the N type semiconductor layer is bonding with the bottom electrode by the bonded layer, and the top electrode is extending and contacting with surface of the P type metal electrode.

In an embodiment, the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain.

In an embodiment, the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.

According to another aspect of the disclosure, the disclosure further provides a method of manufacturing the Micro LED, comprising:

providing a TFT substrate;

opening a hole on top of the TFT substrate and preparing a bottom electrode for extending a bottom of the bottom electrode to conduct with a source or a drain of the TFT substrate;

transferring a Micro LED chip to the bottom electrode;

preparing a first passivation layer for covering the Micro LED chip, the bottom electrode and top surface of the TFT substrate;

opening a via hole on the first passivation layer for exposing the Micro LED chip; and

preparing a top electrode in the via hole.

In an embodiment, while transferring the Micro LED chip to the bottom electrode, the Micro LED chip is bonded to the bottom electrode by the bonded layer.

In an embodiment, the Micro LED chip comprising an emitting-light layer, a N type semiconductor layer and a P type semiconductor layer are respectively positioned beside the emitting-light layer, a transparent conducting layer positioned on surface of the P type semiconductor layer and a P type metal electrode positioned on surface of the transparent conducting layer; while transferring the Micro LED chip to the bottom electrode, the N type semiconductor layer is bonding with the bottom electrode by the bonded layer; while preparing the top electrode in the via hole, the top electrode is extending and contacting with surface of the P type metal electrode.

In an embodiment, the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain.

In an embodiment, the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.

The disclosure directly preparing the Micro LED chip which connecting the bottom electrode and top electrode on the TFT substrate such that greatly decreases thickness of the display panel and also achieves to narrow frame effect. Furthermore, the protecting structure beside the Micro LED chip is entire passivation layer, it does not need multiple manufacture, simplify the preparing process.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a structural schematic view of a Micro LED display panel according to an embodiment of the disclosure;

FIG. 2 is a flow chat diagram of a manufacturing method of a Micro LED display panel according to an embodiment of the disclosure;

FIG. 3 is a part of flow chat diagram of a manufacturing method of a Micro LED display panel according to the embodiment of the disclosure; and

FIG. 4 is another part of flow chat diagram of a manufacturing method of a Micro LED display panel according to the embodiment of the disclosure.

### DETAILED DESCRIPTION OF THE PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

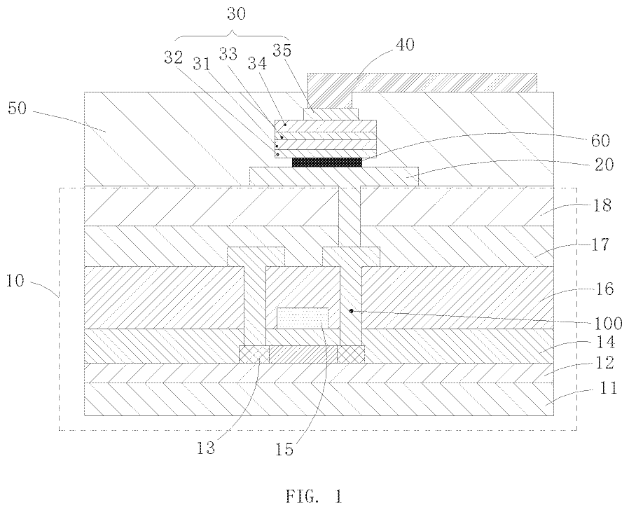

Please refer to FIG. 1. The Micro LED display panel of the embodiment in this disclosure comprises a TFT substrate 10, a bottom electrode 20 is positioned on the top of the TFT substrate 10, a Micro LED chip 30 is positioned on the bottom electrode 20, a top electrode 40 is positioned on top of the Micro LED chip 30, and a first passivation layer 50 is covering the TFT substrate 10 and the Micro LED chip 30. A plurality of the bottom electrode 20 is provided, and positioned at interval on top of the TFT substrate 10. The bottom of the bottom electrode 20 is extending and conducting with a source or a drain 100 of the TFT substrate 10, at least part of the top electrode 40 is positioned outside the first passivation layer 50, and the top of the top electrode 40 is pasting on surface of the first passivation layer 50 for convince connecting with a driving circuit.

Specifically, the Micro LED chip 30 is bonded to the bottom electrode 20 by the bonded layer 60. The Micro LED chip 30 comprising an emitting-light layer 31, a N type semiconductor layer 32 and a P type semiconductor layer 33 are respectively positioned beside the emitting-light layer 31, a transparent conducting layer 34 is positioned on surface of the P type semiconductor layer 33 and a P type metal electrode 35 is positioned on surface of the transparent conducting layer 34, the N type semiconductor layer 32 is bonding with the bottom electrode 20 by the bonded layer 60, and the top electrode 40 is extending and contacting with surface of the P type metal electrode 35,

Usually, the manufacturing method of Micro LED chip 30 is that forming different color Micro LED chip 30 on the sapphire substrate by molecular beam epitaxy, and then transferring the Micro chip LED 30 to the glass substrate. After preparing the Micro LED chip 30, bonding the bottom electrode 20 which correspondingly to the TFT substrate 10 by the bonded layer 60 according to printing process.

Except for the source/the drain 100, the TFT substrate 10 further comprises a substrate 11, a buffer layer 12 is positioned on the substrate 11, an active layer 13 is positioned on the buffer layer 12, a grid insulating layer 14 is positioned on the buffer layer 12 and covering the active layer 13, a grid 15 is positioned on the grid insulating layer 14, and a dielectric layer 16 is positioned on the grid insulating layer 14 and the grid 15, and a second passivation layer 17 is covering on the dielectric layer 16, the second passivation layer 17 is totally covering the source and the drain and avoids the hole collapsing while opening the hole, the source/drain 100 is positioned on surface of the dielectric layer 16 and extending and conducting with the active layer 13 positioned under it.

In addition, surface of the TFT substrate 10 further comprises a planar layer 18, the planar layer 18 is covering surface of the second passivation layer 17 for ensuring the bottom electrode 20 and the first passivation layer 50 have flat manufacturing surface. The bottom electrode 20 is positioned on the surface of the second passivation layer 17 and passing through the second passivation layer 17, and extending to surface of the source or the drain 100 of the TFT substrate 10.

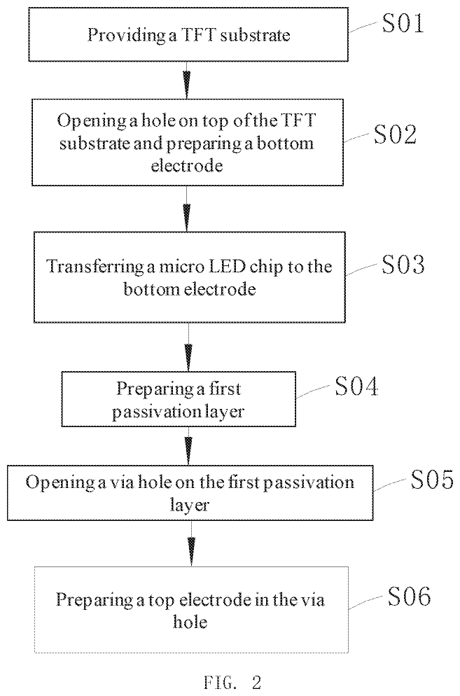

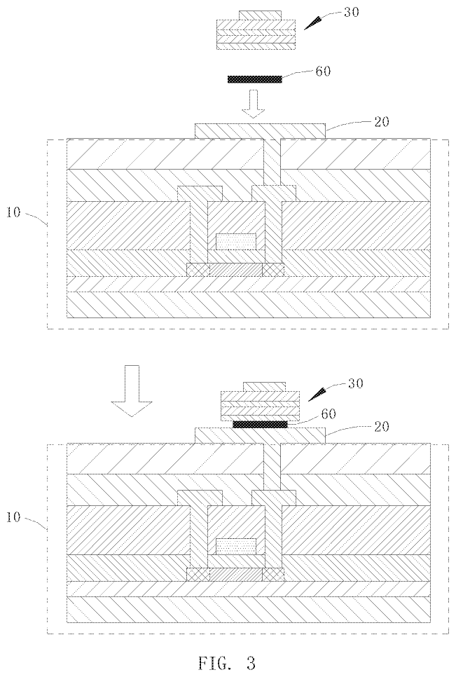

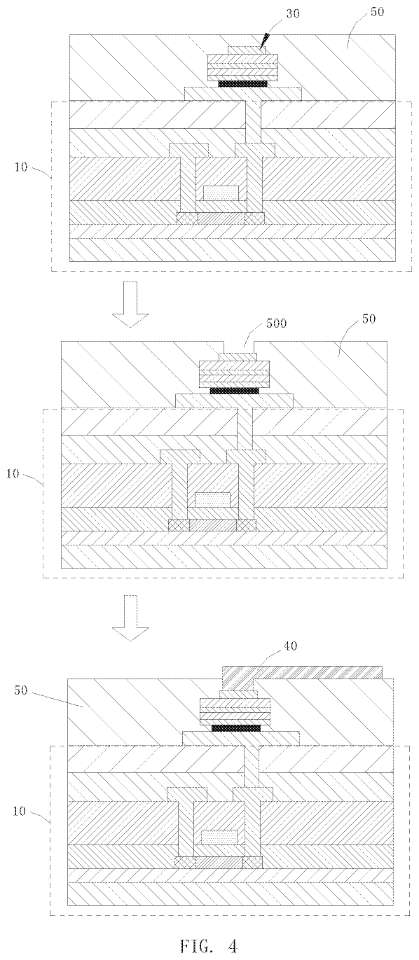

Please refer to FIG. 2 through FIG. 4. A method of manufacturing the Micro LED display panel in this disclosure comprises the following steps.

S01, providing a TFT substrate 10. The TFT substrate 10 comprising a source/a drain 100, a substrate 10, a buffer layer 12 is positioned on the substrate 11, an active layer 13 is positioned on the buffer layer 12, a grid insulating layer 14 is positioned on the buffer layer 12 and covering the active layer 13, a grid 15 is positioned on the grid insulating layer 14, and a dielectric layer 16 is positioned on the grid insulating layer 14 and the grid 15, and a second passivation layer 17 and a planar layer 18 are covering on the dielectric layer 16. The second passivation layer 17 is totally covering the source and the drain. The planar layer 18 is covering on surface of the second passivation layer 17 and extending to surface of the source or the drain 100 of the TFT substrate 10;

S02, opening a hole on top of the TFT substrate 10 and preparing a bottom electrode 20 for extending a bottom of the bottom electrode 20 to conduct with the source or the drain 100 of the TFT substrate 10;

S03, transferring a Micro LED chip 30 to the bottom electrode 20, and the Micro LED chip 30 is bonded to the bottom electrode 20 by the bonded layer 60. Specifically, the Micro LED chip 30 comprises an emitting-light layer 31, a N type semiconductor layer 32 and a P type semiconductor layer 33 are respectively positioned beside the emitting-light layer 31, a transparent conducting layer 34 is positioned on surface of the P type semiconductor layer 33 and a P type metal electrode 35 is positioned on surface of the transparent conducting layer 34. While transferring the Micro LED chip 30 to the bottom electrode 20, the N type semiconductor layer 32 is bonding with the bottom electrode 20 by the bonded layer 60;

S04, preparing a first passivation layer 50, the first passivation layer 50 is totally covering the Micro LED chip 30, the bottom electrode 20 and top surface of the TFT substrate 10;

S05, opening a via hole 500 on the first passivation layer 50 for exposing the Micro LED chip 30;

S06, preparing a top electrode 40 in the via hole 500 for conducting the top electrode 40 with the Micro LED chip 30. This is, the top electrode is extending and contacting to surface of the P type metal electrode 35, and top of the top electrode is pasting to surface of the first passivation layer 50.

The Micro LED chip 30 is totally surrounding by entire first passivation layer 50, so that only needs to preparing a first passivation layer 50 for embedding the Micro LED chip 30 inside in one step. And then opening a via hole 500 on the first passivation layer 50 for exposing the Micro LED chip 30 such that more easily manufacturing the top electrode 40.

In sum, the disclosure is directly preparing the Micro LED chip which connecting the bottom electrode and top electrode on the TFT substrate, the Micro LED chip is directly forming on bottom electrode of the surface of the TFT substrate by bonding way. Therefore, greatly decreases thickness of the display panel and also achieves to narrow frame effect. Furthermore, the protecting structure beside the Micro LED chip is entire passivation layer, it does not need multiple manufacture, simplify the preparing process.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A Micro LED display panel, comprising
a TFT substrate,
a bottom electrode positioned on a top of the TFT substrate,
a Micro LED chip positioned on the bottom electrode,
a top electrode positioned on top of the Micro LED chip, and
a first passivation layer covering the TFT substrate and the Micro LED chip,
wherein a plurality of the bottom electrode is provided, and positioned at interval on top of the TFT substrate,
the bottom of the bottom electrode is extending and conducting with a source or a drain of the TFT substrate, at least part of the top electrode is positioned outside the first passivation layer.

2. The Micro LED display panel according to claim 1, wherein further comprising a bonded layer, the Micro LED chip is bonded to the bottom electrode by the bonded layer.

3. The Micro LED display panel according to claim 2, wherein the Micro LED chip comprising an emitting-light layer, a N type semiconductor layer and a P type semiconductor layer are respectively positioned beside the emitting-light layer, a transparent conducting layer positioned on surface of the P type semiconductor layer and a P type metal electrode positioned on surface of the transparent conducting layer, the N type semiconductor layer is bonding with the bottom electrode by the bonded layer, and the top electrode is extending and contacting with surface of the P type metal electrode.

4. The Micro LED display panel according to claim 1, wherein the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain.

5. The Micro LED display panel according to claim 4, wherein the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.

6. The Micro LED display panel according to claim 2, wherein the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain.

7. The Micro LED display panel according to claim 6, wherein the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.

8. The Micro LED display panel according to claim 3, wherein the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain.

9. The Micro LED display panel according to claim 8, wherein the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.

10. A method of manufacturing the Micro LED display panel, comprising
providing a TFT substrate;
opening a hole on top of the TFT substrate and preparing a bottom electrode for extending a bottom of the bottom electrode to conduct with a source or a drain of the TFT substrate;
transferring a Micro LED chip to the bottom electrode;
preparing a first passivation layer for covering the Micro LED chip, the bottom electrode and top surface of the TFT substrate;
opening a via hole on the first passivation layer for exposing the Micro LED chip; and
preparing a top electrode in the via hole.

11. The method of manufacturing the Micro LED display panel according to claim 10, wherein while transferring the Micro LED chip to the bottom electrode, the Micro LED chip is bonded to the bottom electrode by the bonded layer,

12. The method of manufacturing the Micro LED display panel according to claim 11, wherein the Micro LED chip comprising an emitting-light layer, a N type semiconductor layer and a P type semiconductor layer are respectively positioned beside the emitting-light layer, a transparent conducting layer positioned on surface of the P type semiconductor layer and a P type metal electrode positioned on surface of the transparent conducting layer; while transferring the Micro LED chip to the bottom electrode, the N type semiconductor layer is bonding with the bottom electrode by the bonded layer; while preparing the top electrode in the via hole, the top electrode is extending and contacting with surface of the P type metal electrode.

13. The method of manufacturing the Micro LED display panel according to claim 10, wherein the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain,

14. The method of manufacturing the Micro LED display panel according to claim 13, wherein the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.

15. The method of manufacturing the Micro LED display panel according to claim 11, wherein the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain.

16. The method of manufacturing the Micro LED display panel according to claim 15, wherein the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.

17. The method of manufacturing the Micro LED display panel according to claim 12, wherein the TFT substrate further comprises a substrate, a buffer layer positioned on the substrate, an active layer positioned on the buffer layer, a grid insulating layer positioned on the buffer layer and covering the active layer, a grid positioned on the grid insulating layer, and a dielectric layer is positioned on the grid insulating layer and the grid, and a second passivation layer covering on the dielectric layer, the second passivation layer is totally covering the source and the drain,

18. The method of manufacturing the Micro LED display panel according to claim 17, wherein the TFT substrate further comprises a planar layer, the planar layer covering surface of the second passivation layer, the bottom electrode positioned on the surface of the second passivation layer and passing through the second passivation layer, and extending to surface of the source or the drain of the TFT substrate.
